(19) United States
(12) Patent Application Publication
(10) Pub. No.: US 2024/0428840 A1
(43) Pub. Date: Dec. 26, 2024

(54) MEMORY DEVICE WITH FINE-GRAINED REFRESH

(71) Applicant: Rambus Inc., San Jose, CA (US)

(72) Inventors: Taeksang Song, San Jose, CA (US); Thomas Vogelsang, Jericho, VT (US)

(21) Appl. No.: 18/750,027

(22) Filed: Jun. 21, 2024

Related U.S. Application Data
(60) Provisional application No. 63/523,315, filed on Jun. 26, 2023.

(51) Int. Cl. G11C 11/406

(52) U.S. Cl. CPC G11C 11/40615; G11C 11/40618; G11C 11/40626

(57) ABSTRACT

An integrated circuit (IC) memory device includes an array of storage cells configured into multiple regions. Monitoring circuitry is coupled to each of the multiple regions to detect and generate per-region operating parameter information. Refresh circuitry generates per-region refresh information for the multiple regions based on the per-region operating parameter information.

### CROSS-REFERENCE TO RELATED APPLICATIONS

This application is a Non-Provisional that claims priority to U.S. Provisional Application No. 63/523,315, filed Jun. 26, 2023, entitled MEMORY DEVICE WITH FINE-GRAINED REFRESH, which is incorporated herein by reference in its entirety.

### TECHNICAL FIELD

The disclosure herein relates to memory systems, and more specifically to memory devices, controllers and methods for varying refresh rates on a per-region basis.

### BRIEF DESCRIPTION OF THE DRAWINGS

Embodiments of the disclosure are illustrated by way of example, and not by way of limitation, in the figures of the accompanying drawings and in which like reference numerals refer to similar elements and in which:

FIG. 1 illustrates an exploded view of one embodiment of a stacked-die semiconductor package that includes a memory system that employs per-region non-uniform refresh.

FIG. 2 illustrates a block diagram of one embodiment of circuitry utilized in the stacked-die semiconductor package of FIG. 1.

FIG. 3 illustrates a flowchart of steps for one embodiment of a method of operating the circuitry of FIG. 2.

### DETAILED DESCRIPTION

Embodiments of memory devices, controllers, associated methods and integrated circuits are disclosed herein. One embodiment of a memory device includes an array of storage cells configured into multiple regions. Monitoring circuitry is coupled to each of the multiple regions to detect and generate per-region operating parameter information. Refresh circuitry generates per-region refresh information for the multiple regions based on the per-region operating parameter information. By non-uniformly varying the per-region refresh rates based on per-region operating parameter information, significant power savings and/or enhanced bandwidth utilization efficiency associated with refresh operations may be realized.

Specific embodiments described herein provide apparatus and methods that may vary refresh rates to refresh storage cells on a per-region basis, and in accordance with per-region operating parameter information. Refresh rates may thus be selectively increased or decreased at certain finely-granulated locations to correspondingly refresh storage cells where retention times for those areas, or regions, may be affected by operating parameters such as temperature, voltage and/or access frequency.

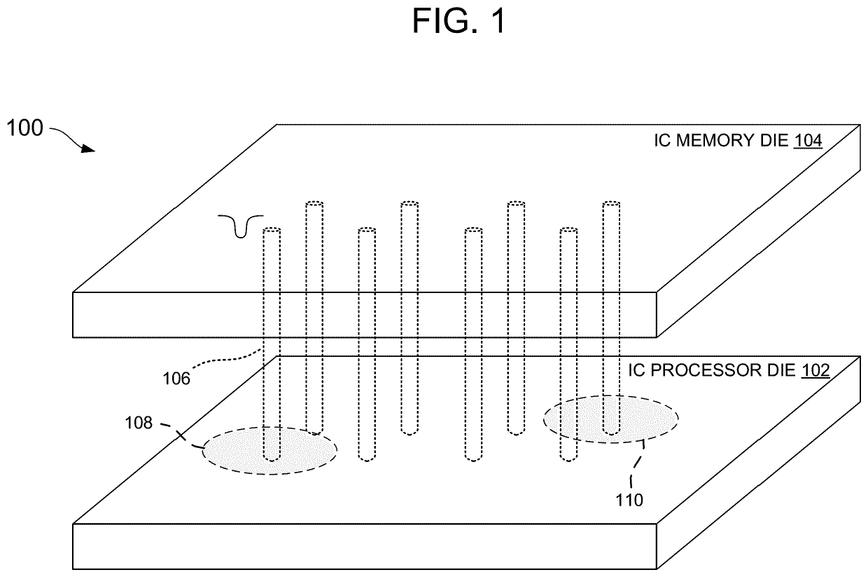

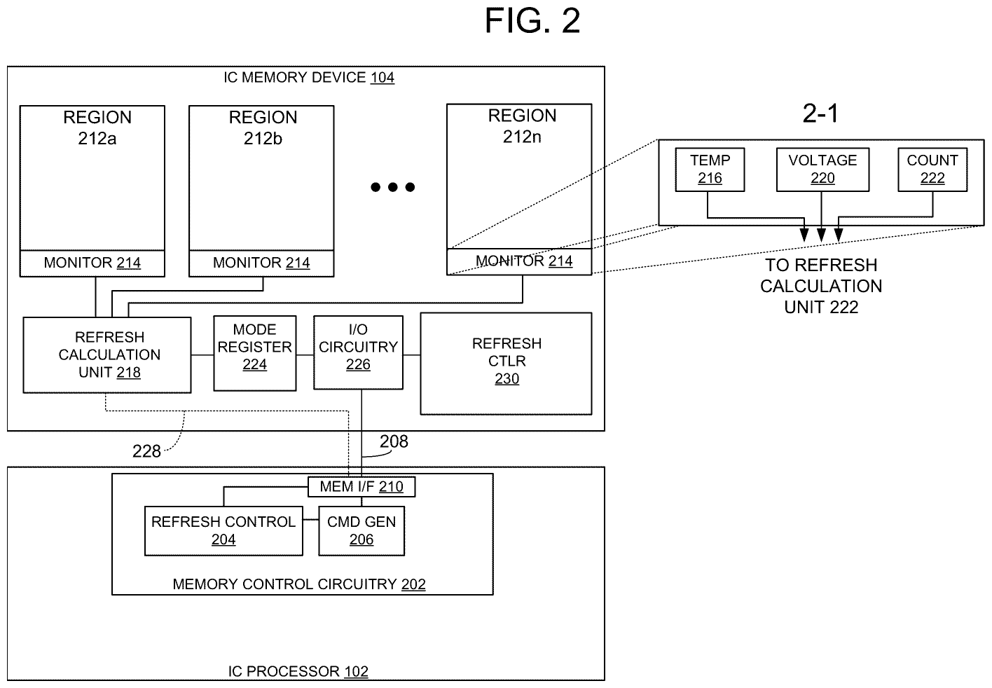

With reference to FIG. 1, a stacked-die semiconductor package, generally designated 100, is shown in an exploded view that includes a first integrated circuit (IC) chip 102 that is vertically-stacked with an IC memory chip 104. A plurality of through-silicon vias (TSVs) 106 interconnect the first IC chip 102 with the IC memory chip 104. In another embodiment, the plurality of connections 106 might be the connections of face-to-face connected chips 102 and 104. For one embodiment, the first IC chip 102 may take the form of a processor chip, such as a computer processing unit (CPU) or graphics processing unit (GPU), with the IC memory chip 102 realized as a dynamic random access (DRAM) memory device or other volatile memory device that utilizes periodic refresh operations to maintain storage cell data states. In some embodiments, the first IC chip 102 employs memory control circuitry 202 (FIG. 2) to control the IC memory chip 104. Specific embodiments for the memory control circuitry 202 and the IC memory device may be compliant with various DRAM standards, including double data rate (DDR) variants, low power (LPDDR) versions, High-Bandwidth Memory (HBM), and graphics (GDDR) types. While the discussions herein relate primarily to the stacked-die semiconductor package 100 embodiment of FIG. 1, in some circumstances, the per-region refresh rate features described herein may be equally beneficial for closely-spaced planar or horizontal die configurations.

While not shown in FIG. 1, the IC memory die 104 generally includes an array of storage cells that are capable of retaining a certain percentage of charge for a given period of time, known as a retention time. To successfully store a given bit of data, each storage cell is generally refreshed at least as often as the retention time of the cell. Certain operating parameters may impact a given storage cell's retention time. As one example, an increase in operating temperature for a DRAM storage cell may cause a reduction in its retention time. A loss in retention time may also be caused by a lower than expected write voltage to the cell. Another operating parameter that may affect retention time includes the number of times a given cell is accessed, which may impact retention times for surrounding cells due to a “row hammer” disturbance.

Further referring to FIG. 1, the first IC chip 102 is shown with localized hot-spots 108 and 110 that represent areas of high-temperature during operation. Thermal conductivity emanating from the hot spots 108 and 110 may result in similar localized areas of increased temperature in the IC memory die 104, especially in areas adjacent the processor hot spots. With memory storage array circuitry generally distributed across the IC memory die 104, in some cases only certain portions of the storage array may be exposed to localized high-temperature regions, while other areas may remain relatively cool.

In an effort to take advantage of situations where different regions of the IC memory device 104 may experience different operating parameters, and thus exhibit different retention times, the stacked-die semiconductor package 100 of FIG. 1 includes refresh circuitry, shown in FIG. 2, that has the ability to establish variable refresh rates for different areas of the IC memory device 104.

Further referring to FIG. 2, for one embodiment, the processor chip 102 employs the memory control circuitry 202 for configuring and controlling transfer operations between the processor chip 102 and the IC memory chip 104. The memory control circuitry 202 includes a refresh controller 204 for handling various configuration and control tasks, explained more fully below, and a refresh command generator 206 for generating refresh commands that are transmitted to the IC memory device 104 along a bus 208 via a memory interface 210.

With continued reference to FIG. 2, one embodiment of the IC memory device 104 includes an array of volatile storage cells that are organized into multiple regions 212a-212n, such as groups of banks, an individual bank, a portion of a bank, a row, or portion of a row. What constitutes a given region may be predefined at manufacture or configured at system initialization/run-time by the memory control circuitry 202 to achieve a desired level of granularity, or refresh rate resolution. While the description herein primarily addresses embodiments involving DRAM memory, the IC memory device 104 may include any memory integrated circuit (IC) chip having volatile storage cells that maintain a given charge state through periodic refresh operations.

With continued reference to FIG. 2, to carry out refresh operations on a per-region basis, one embodiment of the IC memory device 104 incorporates monitoring circuitry 214 to monitor and generate information regarding specified operating parameters for each region. The monitoring circuitry 214 may be realized as separate monitoring circuits for each of the multiple regions, or a block of circuitry that is shared by the multiple regions but capable of monitoring and generating per-region parameter information.

For one embodiment, and shown in detail 2-1, the monitoring circuitry 214 may include a temperature sensor 216 disposed in each defined region to measure and generate temperature information pertaining to that region. As explained above, knowledge of a region's operating temperature may be valuable in understanding if retention times for storage cells in the region should be expected to be similar to default retention times or shortened by an increase in temperature in the region (or even potentially lengthened by a decrease in temperature in the region). The temperature information for each region may then be sent to a refresh calculation unit 218 where a refresh rate for each region may be calculated based at least in part on the temperature information.

Further referring to detail 2-1 of FIG. 2, in addition to or as a substitute for the temperature sensor 216, a voltage monitor 220 may also be employed in each defined region to measure and generate voltage parameter information that may affect storage cell retention times. The voltage monitor 220 may be part of a voltage system associated with the region to measure the relative magnitude of write voltages applied to storage cells in the particular region as compared to a reference voltage. Indications of a low measured voltage with respect to the reference voltage may suggest lower levels of charge stored in each cell during a write operation, contributing to a lower retention time for those cells. Once the voltage information is monitored and generated, it is sent to the refresh calculation unit 218.

For some embodiments, and with continued reference to detail 2-1 of FIG. 2, the per-region monitoring circuitry 214 measures and generates information pertaining to how often a region's storage cells are accessed during read and/or write operations. The access information, often referred to as access frequency, indicates how active a region's cells are during a given period of time. Frequently accessed regions may incur more errors experienced from peripheral disturbances, where a given accessed cell may impact the retention time of one or more neighboring cells through an effect known as “row hammer.” For one embodiment, a row activation counting circuit 222 may be employed to track the access frequency of one or more cells in a particular region. Like the temperature information and voltage information described above, the access frequency information may be fed to the refresh calculation unit 218.

In one embodiment, the refresh calculation unit 218 receives the per-region operating parameter information from the per-region monitoring circuits 214 and calculates a suitable refresh rate for each region based on the measured parameter information. The suitable refresh rate may be an absolute rate, where the rate represents a specific value, or a relative refresh rate that specifies a difference from a default or reference refresh rate. For some embodiments, the absolute or relative refresh rate may be in terms of a minimum required refresh rate. Thus, regions that may be exposed to higher temperatures and/or lower voltages and/or higher access frequencies may be refreshed at a higher refresh rate than a default refresh rate due to the expected loss of retention time. Conversely, in some circumstances, regions that may be exposed to lower temperatures and/or higher voltages and/or lower access frequencies may be refreshed at a lower refresh rate than the default refresh rate due to the expected loss of retention time. Of course, many different combinations of measured parameters may be evaluated by the refresh calculation unit 218 in calculating the per-region refresh rates. Thus, in some circumstances, a given region may experience, for example, a higher temperature with a default voltage level and few accesses. Each of the parameter measurements may thus be assigned fixed or programmable weightings, depending on the application, to correspondingly influence the calculation of the per-region refresh rate.

Further referring to FIG. 2, once the per-region refresh rates are determined by the refresh calculation unit 218, they may be stored in the IC memory device 104 for retrieval by the memory control circuitry 202. For one embodiment, the per-region refresh rates are stored in mode register storage 224 that is accessible via mode register read (MRR) commands generated by the memory control circuitry 202. In response to received MRR commands, the per-region refresh rate values are transferred to the memory control circuitry 202 via memory input/output (I/O) circuitry 226. In other embodiments, the per-region refresh rates may be transferred to the memory control circuitry 202 via a separate interface or backchannel 228 (shown in phantom).

Further referring to FIG. 2, as the memory control circuitry 202 receives the calculated per-region refresh rates from the IC memory chip 104, the refresh control circuitry 204 controls the command generator 206 to dispatch refresh commands for the various regions to carry out refresh operations at the per-region refresh rates calculated by the IC memory device 104. Once the refresh commands are received by the IC memory device 104, a refresh controller 230 in the IC memory device 104 responds to the refresh commands by initiating refresh operations in accordance with the per-region refresh rates for the regions being refreshed.

In operation, per-region refresh operations are generally managed by the memory system of FIG. 2 in auto-refresh situations. Generally, auto-refresh takes place during active operation of an electronic device, where operating parameter effects are more likely to impact retention times, while self-refresh takes place while the electronic device is in a “sleep” or inactive mode to reduce power dissipation. For some embodiments, self-refresh operations may continue to employ the per-region refresh rates initially calculated by the refresh calculation unit, or revert to a global default refresh rate for all of the regions. In addition to having auto-refresh and self-refresh modes of operation, the memory system may include a calibration or initialization mode of operation and a normal or full-rate mode of operation.

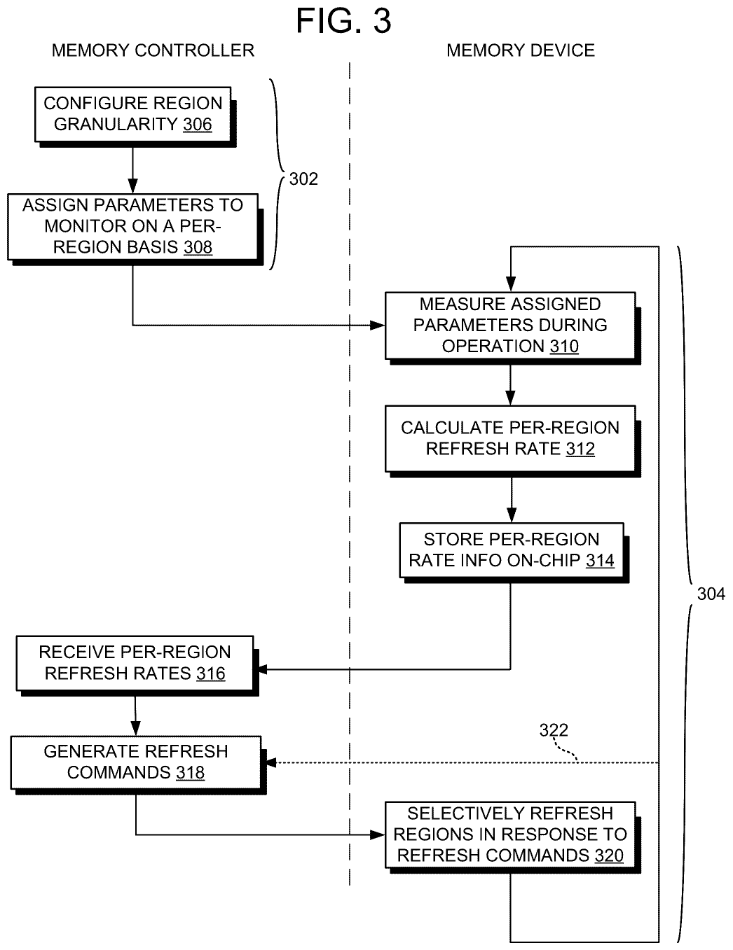

FIG. 3 illustrates one embodiment of various steps involved during operation of the memory system of FIG. 2, in both an initialization mode of operation, at 302, and a normal mode of operation, at 304. Prior to entering the normal mode of operation 304, a configuration procedure may be carried out during the initialization mode of operation 302 to initialize and configure various memory system settings. The configuration procedure may involve having the memory control circuitry 202 configuring the region granularity, at 306. As noted earlier, the region size or granularity may be predefined based on the expected system applications (and expected locations of potential hotspots) or selected from a range of region sizes that may include, for example, individual memory die, groups of banks on one or more of the die, an individual bank, a portion of a bank, a row, or portion of a row.

Once the region granularity is configured, the memory control circuitry 202 may also assign, configure and/or confirm the parameters that will be monitored by the memory device 104 on a per-region basis, at 308. In some embodiments, the refresh calculation unit 218 on the IC memory device 104 tailors its calculation algorithm to take into account the parameters that are actually monitored by the monitoring circuitry 214.

Once the configuration procedure is complete, the memory system may transition from the initialization mode of operation 302 and into the normal mode of operation 304. During the normal mode of operation, the IC memory device 104 will generally perform various read, write and maintenance operations (such as refresh) in close proximity to the processor 102 (FIG. 1). While carrying out its primary read, write and maintenance tasks, in the background the per-region monitoring circuitry 214 measures the assigned operating parameters (such as temperature, voltage and/or access frequency), and generates per-region parameter information, at 310.

Further referring to FIG. 3, as the per-region parameter information is generated and fed by the per-region monitoring circuitry 212 to the refresh calculation unit 218, separate refresh rates for each region are calculated, at 312, based on the per-region parameter information, and periodically updated. The frequency of the updates may be based on various criteria, such as when certain parameter thresholds are triggered, or at fixed time intervals, or adaptive in response to detected transient activity in certain regions. In some embodiments, the IC memory device 104 may send an alert signal or other indicator to the memory control circuitry 202 when a given region's refresh rate is updated.

For some embodiments, in addition to using the measured parameter information as a factor in calculating the pre-region refresh rates, the refresh calculation unit 218 evaluates the operating environment in a manner that can determine when certain regions of the IC memory device 104 may be more susceptible to external disturbances. The external disturbances may involve power supply noise, row hammer effects, and other transient activity. For some situations, disturbance evaluation information may supplement the parameter information in calculating the per-region refresh rates.

Further referring to FIG. 3, for one embodiment, once the per-region refresh rate information is calculated, it may be stored in the on-chip register storage 224, at 314. The memory control circuitry 202 then periodically retrieves the stored per-region refresh rate information from the register storage 224 via mode register read (MRR) commands that are sent along with other memory operation command information. For some embodiments, in addition to, or as an alternative to storing the per-refresh rate information on-chip, the IC memory device 104 may immediately send the per-region refresh rate information to the memory control circuitry 202 via the direct backchannel or interface separate from the main interface bus 208.

With continued reference to FIG. 3, as the per-region refresh rate information is received at the memory control circuitry 202, at 316, it is fed to the refresh command generator 206 to generate refresh commands, at 318, for dispatch to the IC memory device 104. The per-region refresh commands generally correspond to the per-region refresh rate information. In some instances, however, the refresh commands may be generated by further taking into account acceptable bit errors (in response to a lower refresh rate) for certain regions but not others. Additionally, the memory control circuitry 202 may group together regions having matching calculated refresh rates such that the granularity of the resulting refresh commands differs from the granularity (now groups of regions) of the separate defined regions.

Further referring to FIG. 3, the IC memory device 104 receives the generated refresh commands and responds by selectively initiating and carrying out refresh operations, at 320, for storage cells corresponding to the specified regions of the refresh commands. For some embodiments, the measuring of the assigned parameters, at 310, and the calculating of the per-region refresh rates, at 312, may occur continuously or periodically after the regions undergo one or more periods of refresh operations. For other embodiments, the measuring of parameters and calculating of per-region refresh rates may occur less often, with the memory control circuitry 202 and the IC memory device 104 carrying out previously established per-region refresh operations directly, via flow path 322. For some embodiments, the memory device may augment received refresh commands that are received at a certain rate, and ignore a portion of the commands to thus effect a reduced refresh rate.

The memory system, device, and method described above provides finer-granularity per-region non-uniform refresh that allows for more efficient power savings achievable by the memory system. The embodiments described herein lend themselves well to stacked die applications where power and bandwidth efficiency is a key concern.

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

In the foregoing description and in the accompanying drawings, specific terminology and drawing symbols have been set forth to provide a thorough understanding of the present disclosure. In some instances, the terminology and symbols may imply specific details that are not required to practice aspects of the disclosure. For example, any of the specific numbers of bits, signal path widths, signaling or operating frequencies, component circuits or devices and the like may be different from those described above in alternative embodiments. Also, the interconnection between circuit elements or circuit blocks shown or described as multi-conductor signal links may alternatively be single-conductor signal links, and single conductor signal links may alternatively be multi-conductor signal links. Signals and signaling paths shown or described as being single-ended may also be differential, and vice-versa. Similarly, signals described or depicted as having active-high or active-low logic levels may have opposite logic levels in alternative embodiments. Component circuitry within integrated circuit devices may be implemented using metal oxide semiconductor (MOS) technology, bipolar technology or any other technology in which logical and analog circuits may be implemented. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘<̅s̅i̅g̅n̅a̅l̅ n̅a̅m̅e̅>̅’) is also used to indicate an active low signal. The term “coupled” is used herein to express a direct connection as well as a connection through one or more intervening circuits or structures. Integrated circuit device “programming” may include, for example and without limitation, loading a control value into a register or other storage circuit within the device in response to a host instruction and thus controlling an operational aspect of the device, establishing a device configuration or controlling an operational aspect of the device through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The term “exemplary” is used to express an example, not a preference or requirement.

While aspects of the disclosure have been described with reference to specific embodiments thereof, it will be evident that various modifications and changes may be made thereto without departing from the broader spirit and scope of the disclosure. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

We claim:

1. An integrated circuit (IC) memory device comprising:
an array of storage cells configured into multiple regions;
monitoring circuitry coupled to each of the multiple regions, the monitoring circuitry to detect and generate per-region operating parameter information; and
refresh circuitry to generate per-region refresh information for the multiple regions based on the per-region operating parameter information.

2. The IC memory device of claim 1, wherein the refresh circuitry refreshes each of the multiple regions during auto-refresh operations in response to refresh commands received from memory control circuitry, the refresh commands based on the per-region refresh information.

3. The IC memory device of claim 1, wherein the array of storage cells comprises:
dynamic random access memory (DRAM) storage cells.

4. The IC memory device of claim 1, further comprising:
storage to store the per-region refresh information.

5. The IC memory device of claim 4, wherein the storage comprises:
register storage.

6. The IC memory device of claim 5, further comprising:
transmit circuitry to transmit the per-region refresh information to memory control circuitry in response to a mode register read (MRR) command.

7. The IC memory device of claim 1, wherein the monitoring circuitry comprises:
at least one of
temperature sensing circuitry;
voltage sensing circuitry; or
access count circuitry.

8. The IC memory device of claim 1, wherein:
the refresh circuitry generates the per-region refresh information as representations of absolute refresh rates for the multiple regions.

9. The IC memory device of claim 1, wherein:
the refresh circuitry generates the per-region refresh information as representations of relative refresh rates for the multiple regions.

10. A method of operation in a memory device, the method comprising:
storing data in an array of storage cells, the array of storage cells configured into multiple regions;
monitoring, with on-die per-region monitoring circuitry, at least one operating parameter in each of the multiple regions;
determining, with on-die refresh control circuitry, per-region operating parameter information from the monitoring; and
generating, with the on-die refresh control circuitry, per-region refresh information for the multiple regions based on the per-region operating parameter information.

11. The method of claim 10, further comprising:
refreshing each of the multiple regions during auto-refresh operations in response to refresh commands received from memory control circuitry, the refresh commands based on the per-region refresh information.

12. The method of claim 10, further comprising:
storing the per-region refresh information in register storage.

13. The method of claim 12, further comprising:
transmitting the per-region refresh information from the register storage to memory control circuitry in response to a mode register read (MRR) command.

14. The method of claim 10, wherein the monitoring comprises:
at least one of
sensing an operating temperature of each of the multiple regions;
sensing a voltage of each of the multiple regions; or
counting a number of accesses made to each of the multiple regions.

15. The method of claim 10, wherein the storing data is carried out in accordance with a dynamic random access memory (DRAM) protocol.

16. An integrated circuit (IC) dynamic random access memory (DRAM) device, comprising:
an array of DRAM storage cells configured into multiple refresh regions;
monitoring circuitry coupled to each of the multiple refresh regions, the monitoring circuitry to detect and generate per-region operating parameter information;
refresh circuitry to generate per-region refresh rate information for the multiple refresh regions based on the per-region operating parameter information; and
mode register storage to store the per-region refresh rate information.

17. The IC DRAM device of claim 16, further comprising:
transmit circuitry to transmit the per-region refresh rate information to memory control circuitry in response to a mode register read (MRR) command.

18. The IC DRAM device of claim 17, wherein:
the refresh circuitry refreshes each of the multiple refresh regions during auto-refresh operations in response to refresh commands received from the memory control circuitry, the refresh commands based on the per-region refresh rate information.

19. The IC DRAM device of claim 16, wherein:
the refresh circuitry generates the per-region refresh rate information as representations of absolute refresh rates for the multiple refresh regions.

20. The IC DRAM device of claim 16, wherein:
the refresh circuitry generates the per-region refresh rate information as representations of relative refresh rates for the multiple refresh regions.
